(19) United States
(12) Patent Application Publication
(10) Pub. No.: US 2025/0227963 A1
(43) Pub. Date: Jul. 10, 2025

(54) TRANSISTOR STRUCTURE WITH HIGHER JUNCTION BREAKDOWN VOLTAGE

(71) Applicant: Taiwan Semiconductor Manufacturing Company, LTD., Hsinchu (TW)

(72) Inventors: Yi-Huan Chen, Hsinchu (TW); Jhu-Min Song, Nantou (TW); Chien-Chih Chou, Taipei (TW); Fei-Yun Chen, Hsinchu (TW)

(21) Appl. No.: 18/408,944

(22) Filed: Jan. 10, 2024

(51) Int. Cl. H01L 29/78; H01L 29/66

(52) U.S. Cl. CPC H10D 30/797; H10D 30/601; H10D 62/021

(57) ABSTRACT

Transistors with strained source drain (SDD) structures are suitable for high voltage applications. A gate stack is present upon the substrate that includes a gate dielectric layer and a gate structure upon the gate dielectric layer. A gate spacer is present on the sidewalls of the gate stack. Two lightly doped drain (LDD) regions extend from below the gate stack towards opposite sides of the gate stack. A plurality of strained source and drain (SSD) structures are present within each LDD region. The SSD structures do not extend below the gate spacers. The transistor can be used in high voltage devices and still avoid junction breakdown.

### BACKGROUND

Integrated circuits are formed on a semiconductor wafer. Photolithographic patterning processes use ultraviolet light to transfer a desired mask pattern to a photoresist on a semiconductor wafer. Etching processes may then be used to transfer to the pattern to a layer below the photoresist. This process is repeated multiple times with different patterns to build different layers on the wafer substrate and make a useful device.

An integrated circuit is made of large numbers of transistors. A field-effect transistor is generally composed of a substrate on which an electrically conductive gate electrode controls the flow of current between a source electrode and a drain electrode. An electrically insulating gate dielectric layer separates the gate electrode from the source and drain electrodes. A semiconductor layer bridges the source and drain electrodes, and is in contact with the gate dielectric layer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a Y-axis cross-sectional view showing a first example embodiment of a transistor structure, in accordance with some embodiments of the present disclosure.

FIG. 1B is a plan view of the first example embodiment.

FIG. 2 is a flow chart illustrating a method for forming the transistor structure, in accordance with some embodiments. Various steps of this method are shown in FIGS. 3-16.

FIG. 3 is a Y-axis cross-sectional view of a substrate prior to beginning the method of FIG. 2.

FIG. 4 is a Y-axis cross-sectional view of the substrate after forming one or more isolation regions to define an active region.

FIG. 5 is a Y-axis cross-sectional view of the substrate after formation of lightly doped drain (LDD) regions on opposite sides of the active region.

FIG. 6 is a Y-axis cross-sectional view of the substrate after forming a gate stack that includes a gate dielectric layer and a dummy gate. The gate stack overlaps the two LDD regions.

FIG. 7 is a Y-axis cross-sectional view of the substrate after forming a sealing layer upon the sidewalls of the gate stack.

FIG. 8 is a Y-axis cross-sectional view of the substrate after two sealing layers and gate spacers are formed on the sidewalls of the gate stack.

FIG. 9A is a Y-axis cross-sectional view of the substrate after etching a plurality of S/D recesses or trenches into each exposed LDD region on the two sides of the gate stack.

FIG. 9B is a set of S/D trench cross-sectional etching profiles that can be formed, depending on the concentration of retardant present in the etching gas.

FIG. 10 is a Y-axis cross-sectional view of the substrate after performing epitaxy to obtain strained source and drain (SSD) structures in the S/D recesses.

FIG. 11 is a Y-axis cross-sectional view of the substrate after an interlayer dielectric (ILD) is formed over the S/D regions.

FIG. 12 is a Y-axis cross-sectional view of the substrate after removal of the dummy gate.

FIG. 13 is a Y-axis cross-sectional view of the substrate after a first insulating layer is applied over the transistor.

FIG. 14 is a Y-axis cross-sectional view of the substrate after vias are formed through the first insulating layer to the gate structure and the SSD structures.

FIG. 15A is a Y-axis cross-sectional view of the substrate after a second insulating layer has been applied over the first insulating layer, and pads are formed in the second insulating layer to form a source electrode, a drain electrode, and a gate electrode, to form a transistor package.

FIG. 15B is a Y-axis cross-sectional view of yet another embodiment of a transistor package, in accordance with the present disclosure. Here, only one insulating layer has been applied.

FIG. 16 is a perspective view of another embodiment of a transistor package, showing the gate electrode can be offset from the source electrode and the drain electrode along the X-axis.

FIG. 17 is a Y-axis cross-sectional view of another embodiment of the transistor, in accordance with the present disclosure. Here, the gate dielectric layer is formed in a recess in the substrate.

FIG. 18 is a Y-axis cross-sectional view of another embodiment of the transistor, in accordance with the present disclosure. Here, the gate dielectric layer and the gate structure extend into a recess in the substrate.

FIG. 19 is a perspective view of another embodiment of the transistor, in accordance with the present disclosure. Here, the transistor is in the form of a FinFET with a three-dimensional structure.

FIG. 20 is a Y-axis cross-sectional view through line A-A of FIG. 19, showing the structure of the gate stack.

FIG. 21 is a Y-axis cross-sectional view through line B-B of FIG. 19, showing the SSD structure.

FIG. 22 is a flow chart illustrating a method for forming the FinFET structure of FIGS. 19-21, in accordance with some embodiments.

FIG. 23 is a graph of drain leakage current vs. drain voltage. The y-axis is logarithmic, while the y-axis is linear.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The present disclosure relates to structures which are made up of different layers. When the terms “on” or “upon” are used with reference to two different layers (including the substrate), they indicate merely that one layer is on or upon the other layer. These terms do not require the two layers to directly contact each other, and permit other layers to be between the two layers. For example all layers of the structure can be considered to be “on” the substrate, even though they do not all directly contact the substrate. The term “directly” may be used to indicate two layers directly contact each other without any layers in between them. In addition, when referring to performing process steps to the substrate or upon the substrate, this should be construed as performing such steps to whatever layers may be present on the substrate as well, depending on the context.

The present disclosure relates to transistor structures with higher source/drain (S/D) junction breakdown voltages, methods for making such transistor structures, and methods for using such structures. Stress/strain techniques are used to increase carrier mobility in transistor channels and improve device performance. The strains parallel to the length and width of the transistor channel are known as in-plane strains. It is known that a biaxial in-plane tensile strain can improve N-type metal-oxide-semiconductor (NMOS) performance, and compressive strain parallel to the channel length direction can improve P-type metal-oxide-semiconductor (PMOS) performance. However, high-voltage devices usually do not use such stress/strain techniques because they result in lower junction breakdown voltages, which is especially undesirable at high voltages (greater than 9 volts). The present disclosure describes structures which can include strain engineered source/drain regions and still maintain high junction breakdown voltages.

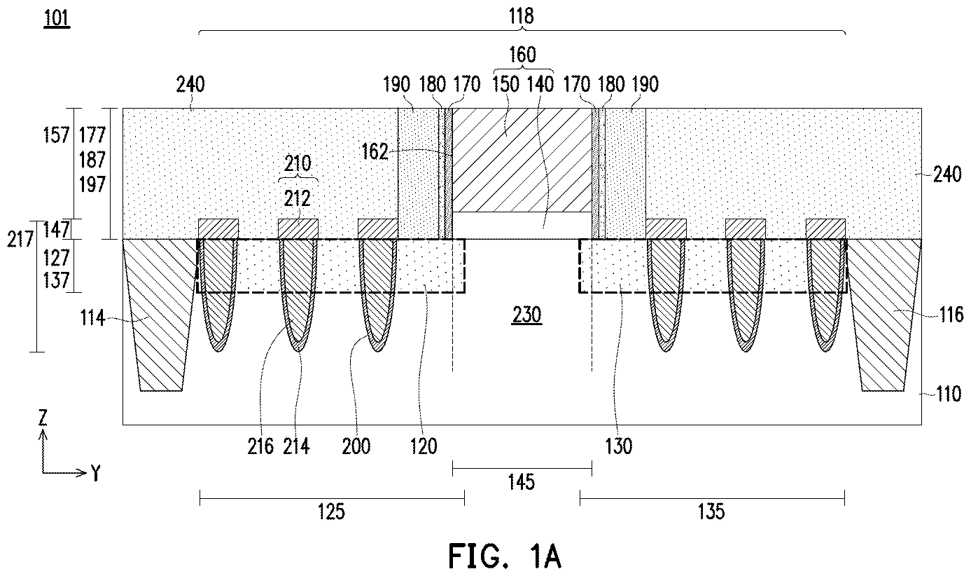

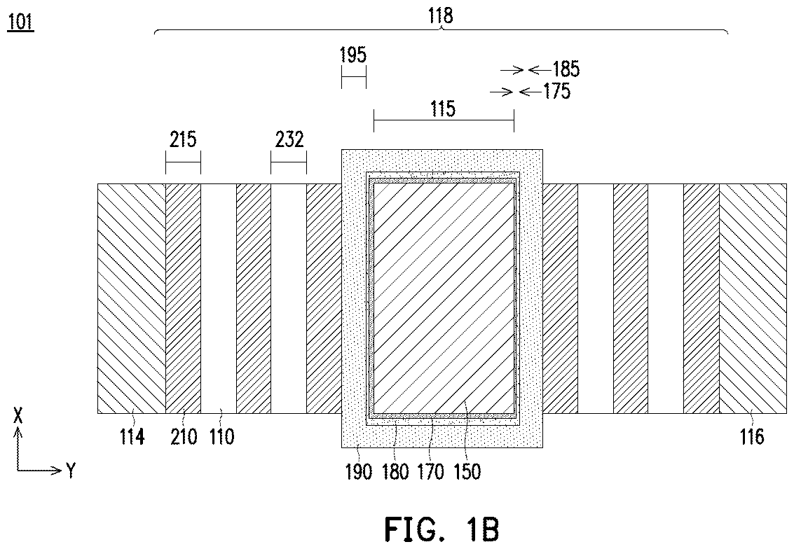

FIG. 1A is a Y-axis cross-sectional view showing a first example embodiment of a transistor structure 101, in accordance with some embodiments of the present disclosure, and illustrating some features. FIG. 1B is a plan view of the first example embodiment, near the upper surface of the substrate.

Referring to both figures together, the transistor 101 is formed on a substrate 110. Two isolation regions 114, 116 are present, which may be, for example, shallow trench isolation (STI) regions or deep trench isolation (DTI) regions. The area between them is defined as an active region 118. It is noted that there may also be isolation regions in the X-axis (not illustrated), so that the active region is surrounded on all sides. Alternatively, the isolation regions 114, 116 can together be considered as one isolation region since they are formed in the same step and are physically connected together.

Two lightly doped drain (LDD) regions 120, 130 are present in the substrate on opposite sides of the active region. LDD region 120 extends from isolation region 114 towards the center of the active region, and LDD region 130 extends from isolation region 116 towards the center of the active region. The two LDD regions 120, 130 do not contact each other, and are spaced apart from each other.

A gate stack 160 is also present in the active region upon the substrate. The gate stack includes a gate dielectric layer 140 and a gate structure 150 upon the gate dielectric layer 140. The gate stack 160 overlaps both LDD regions 120, 130, or in other words a portion of the gate stack is located vertically above each LDD region. The LDD regions can also be described as extending away from the gate stack towards opposite sides of the active region.

An optional first sealing layer 170 is present upon the sidewalls 162 of the gate stack and oriented vertically. An optional second sealing layer 180 contacts the first sealing layer 170 and is also oriented vertically. A gate spacer 190 contacts the second sealing layer 180 and is also oriented vertically. The optional first sealing layer 170, the optional second sealing layer 180, and the gate spacer 190 can each be described as being formed upon the sidewalls 162 of the gate stack. As better seen in the plan view of FIG. 1B, these three layers 170, 180, 190 surround the gate stack 160. These three layers are typically made from a dielectric material.

A plurality of source/drain (S/D) trenches 200 is present in each LDD region 120, 130. Here, three S/D trenches are illustrated in each LDD region. The S/D trenches are spaced apart from each other. Each trench contains a strained source and drain (SSD) structure 210. A capping portion 212 of the SSD structure is present above the substrate 110. Notably, the SSD structures 210 do not extend below the gate spacer 190. Dashed lines indicate the location of the semiconductor channel 230, and the SSD structures 210 are spaced apart from the semiconductor channel. Interlayer dielectric (ILD) regions 240 are present over the S/D trenches 200.

Very generally, an SSD structure is formed by introducing a dopant into silicon to increase the interatomic distance and change the lattice structure. This induces strain or stress in the semiconductor channel 230. The dopant concentration in the SSD structure is in the form of a gradient, with the highest dopant concentration being present along the perimeter or the walls of the SSD structure, and the lowest dopant concentration being present near the center of the SSD structure. As illustrated here, the low-dopant-concentration volume is indicated with reference number 214, and the high-dopant-concentration volume is indicated with reference number 216. In particular embodiments, in the low-dopant-concentration volume, the dopant concentration may be from about 1×10¹⁹ (1E19) to about 5×10²⁰ (5E20) atoms/cc. In the high-dopant-concentration volume, the dopant concentration may be from about 5×10²⁰ (5E20) to about 5×10²¹ (5E21) atoms/cc. The dopant concentration generally changes smoothly from the perimeter to the center.

Each LDD region 120, 130 has a width 125, 135 and a depth 127, 137. In particular embodiments, the widths 125, 135 are independently from about 200 nanometers (nm) to about 1000 nm. In particular embodiments, the depths 127, 137 are independently from about 50 nm to about 300 nm. Combinations of the width and depth are also contemplated. Other ranges and values for each of these properties are also within the scope of this disclosure.

The gate dielectric layer 140 has a width 145 and a depth 147. In particular embodiments, the width 145 is from about 300 nm to about 1000 nm. In particular embodiments, the depth 147 is from about 10 nm to about 30 nm. Combinations of the width and depth are also contemplated. Other ranges and values for each of these properties are also within the scope of this disclosure.

The gate structure 150 has a width 155 and a depth 157. In particular embodiments, the width 155 is from about 300 nm to about 1000 nm. In particular embodiments, the depth 157 is from about 10 nm to about 100 nm. Combinations of the width and depth are also contemplated. Other ranges and values for each of these properties are also within the scope of this disclosure.

The first sealing layer 170 has a width 175 and a depth 177. In particular embodiments, the width 175 is from about 10 nm to about 30 nm. In particular embodiments, the depth 177 is from about 30 nm to about 100 nm. Combinations of the width and depth are also contemplated. Other ranges and values for each of these properties are also within the scope of this disclosure.

The second sealing layer 180 has a width 185 and a depth 187. In particular embodiments, the width 185 is from about 10 nm to about 30 nm. In particular embodiments, the depth 187 is from about 30 nm to about 100 nm. Combinations of the width and depth are also contemplated. Other ranges and values for each of these properties are also within the scope of this disclosure.

The gate spacer 190 has a width 195 and a depth 197. In particular embodiments, the width 195 is from about 10 nm to about 30 nm. In particular embodiments, the depth 197 is from about 30 nm to about 100 nm. Combinations of the width and depth are also contemplated. Other ranges and values for each of these properties are also within the scope of this disclosure.

The dimensions of the S/D trench 200 and the SSD structure 210 can be discussed together. Each SSD structure has a width 215 and a depth 217. In particular embodiments, the width 215 is from about 10 nm to about 100 nm. In particular embodiments, the depth 217 is from about 30 nm to about 100 nm. Combinations of the width and depth are also contemplated. Other ranges and values for each of these properties are also within the scope of this disclosure.

Adjacent S/D trenches and SSD structures are spaced apart from each other by a spacing width 232. In particular embodiments, the width 232 is from about 10 nm to about 100 nm. Other ranges and values are also within the scope of this disclosure.

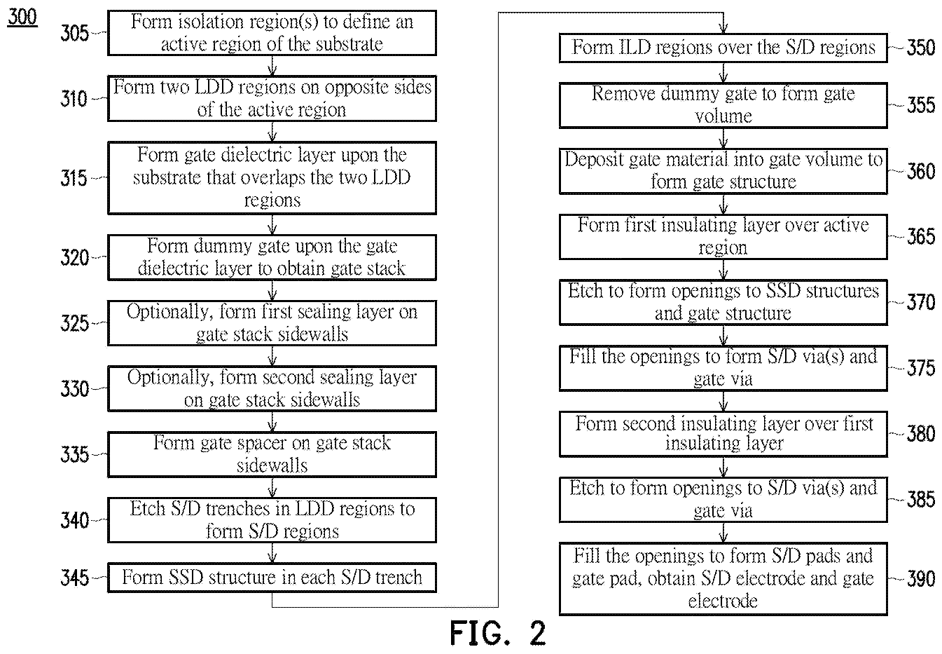

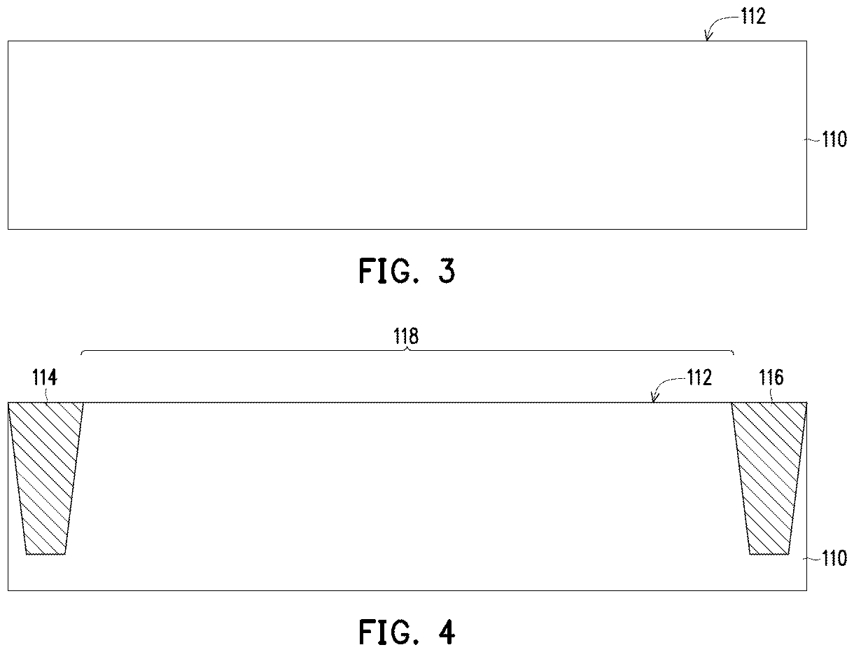

FIG. 2 is a flow chart illustrating a first method 300 for making a transistor structure, in accordance with some embodiments. Some steps of the method are also illustrated in FIGS. 3-16. These figures provide different views for better understanding. While the method steps are discussed below in terms of forming a single transistor structure, such discussion should also be broadly construed as applying to the concurrent formation of multiple transistors.

FIG. 3 is a cross-sectional view of a substrate 110 upon which the transistor will be formed. The substrate may be, for example, a wafer made of a semiconducting material. Such semiconductor materials can include silicon, for example in the form of crystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the substrate is silicon. The substrate includes an upper surface 112.

In step 305 of FIG. 2 and as illustrated in FIG. 4, one or more isolation regions are formed in the substrate 110 to define an active region 118 of the substrate. As illustrated here, two shallow trench isolation (STI) regions 114, 116 are formed in the substrate. The active region 118 is located in the area between the two STI regions 114, 116. As previously mentioned, when considered in three dimensions, the two STI regions may be linked to each other and could be considered as one isolation region.

The isolation regions are formed by patterning the substrate, etching the trenches, and filling the trenches with a dielectric material. The dielectric material in the STI region is commonly silicon dioxide, although other dielectric materials can also be used such as undoped polysilicon, silicon oxide (e.g. SiO₂), silicon nitride, silicon oxynitride, fluoride-doped silicate glass, or other low-k dielectric material. The deposition can be done using physical vapor deposition (PVD) or chemical vapor deposition (CVD) or spin-on processes known in the art, or can be grown via oxidation. If desired, the dielectric material can be deposited to a level above that of the substrate upper surface 112, then recessed back down to the desired height.

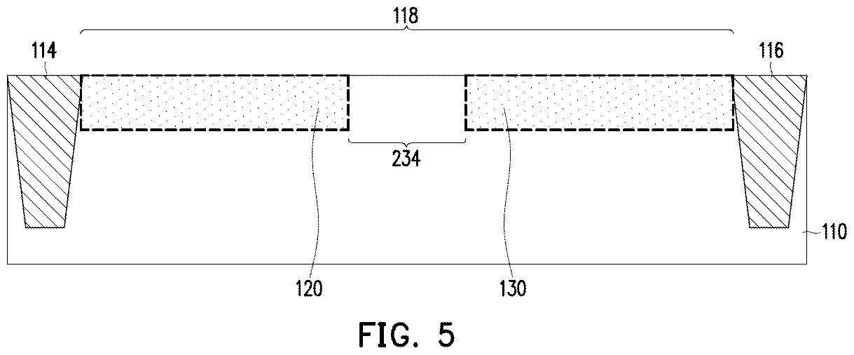

In step 310 of FIG. 2 and as illustrated in FIG. 5, two lightly doped drain (LDD) regions 120, 130 are formed in the substrate on opposite sides of the active region 118. The LDD region reduces the hot carrier effect that can occur in the saturation region of the transistor. As illustrated here, the first LDD region 120 extends from one STI region 114 towards the center or middle of the active region. Similarly, the second LDD region 130 extends from the other STI region 116 towards the center or middle of the active region. However, the two LDD regions 120, 130 do not contact each other. Put another way, there is a gap 234 between the two LDD regions.

The LDD regions may be made by ion implantation or other suitable methods. Briefly, in ion implantation, an ion implanter is used to implant atoms into a silicon crystal lattice, modifying the conductivity of the lattice in the implanted location. An ion implanter generally includes an ion source, a beam line, and a process chamber. The ion source produces the desired ions. The beam line organizes the ions into a beam having high purity in terms of ion mass, energy, and species. A mask, such as a patterned photoresist layer or a hard mask layer, is used to expose desired regions of the substrate. The ion beam is then used to irradiate the semiconducting wafer substrate in a process chamber. The ion beam strikes the exposed regions on the wafer substrate, and the ions can be implanted into the substrate as dopants at desired depths. Alternatively, the substrate can be partially etched, followed by blanket deposition of the dopant, following by annealing in which the dopant reacts with the underlying exposed silicon.

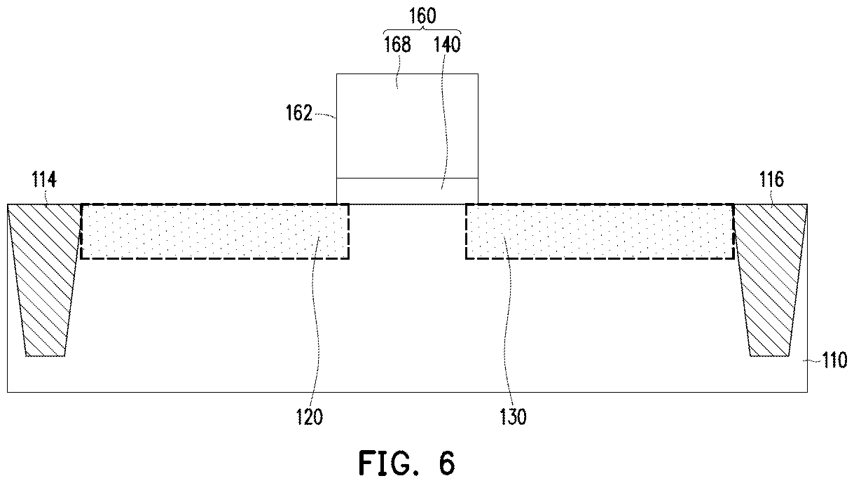

Next, in step 315 of FIG. 2 and as illustrated in FIG. 6, a gate dielectric layer 140 is formed upon the substrate 110. Again, CVD, PVD, atomic layer deposition (ALD), or other suitable deposition process may be used to form the gate dielectric layer. Thermal oxidation may also be used. Then, in step 320 of FIG. 2, a dummy gate 168 is formed upon the gate dielectric layer 140. The dummy gate is commonly made of polysilicon. The dummy gate may be formed using suitable processes such as CVD, PVD, ALD, or other deposition techniques. The resulting structure is shown in FIG. 6. The gate dielectric layer 140 and the dummy gate 168 may be referred to together as a gate stack 160. As seen here, the gate stack 160 bridges the gap between the two LDD regions 120, 130. Put another way, the gate stack overlaps the two LDD regions. The gate stack has sidewalls 162.

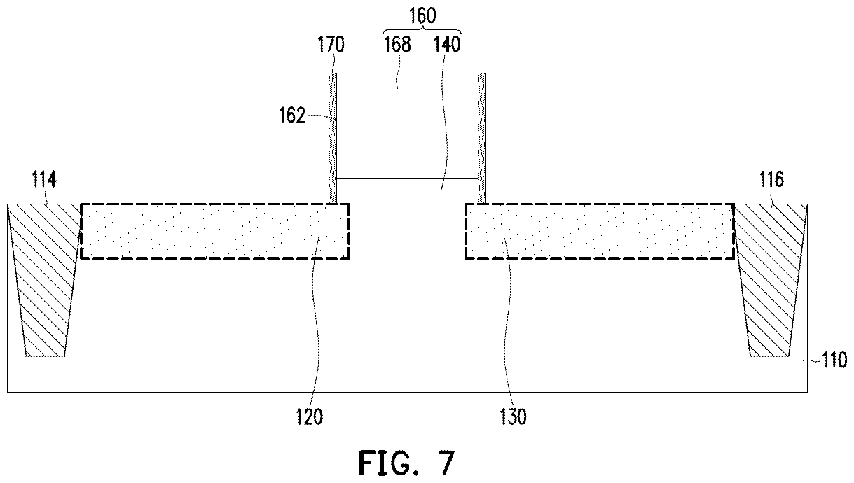

Next, in optional step 325 of FIG. 2 and as illustrated in FIG. 7, a first sealing layer 170 may optionally be formed upon the sidewalls 162 of the gate stack. The first sealing layer 170 is vertically oriented, and has a relatively narrow width. The first sealing layer is made from a dielectric material for electrical isolation of the final gate. In particular embodiments, the first sealing layer is silicon nitride (SiN) or silicon dioxide (SiO₂). The first sealing layer can be made by CVD, PVD, ALD, or other deposition technique.

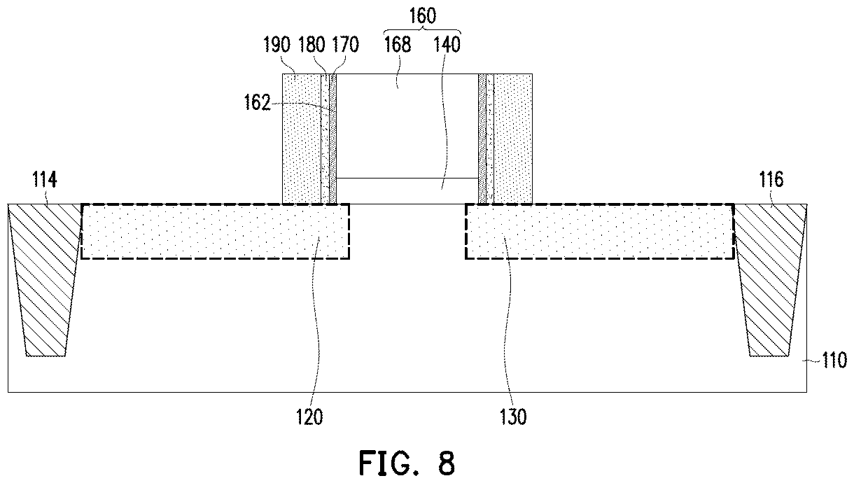

Referring now to FIG. 8, similarly, in optional step 330 of FIG. 2, a second sealing layer 180 may optionally be formed upon the sidewalls 162 of the gate stack, upon the first sealing layer 170. Then in step 335 of FIG. 2, a gate spacer is formed upon the sidewalls of the gate stack. In particular embodiments, the gate spacer is silicon nitride (SiN) or silicon dioxide (SiO₂). The gate spacer can be made by CVD, PVD, ALD, or other deposition technique. As illustrated here, the gate spacer 190 is formed over the LDD regions 120, 130.

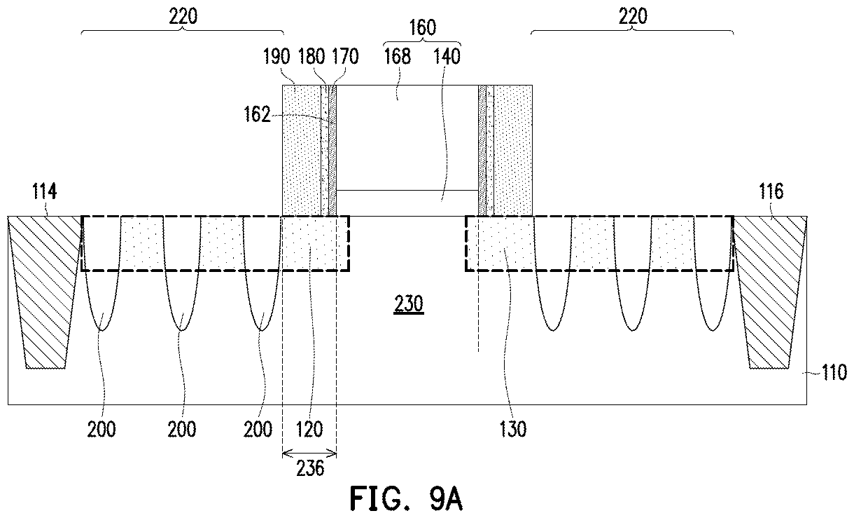

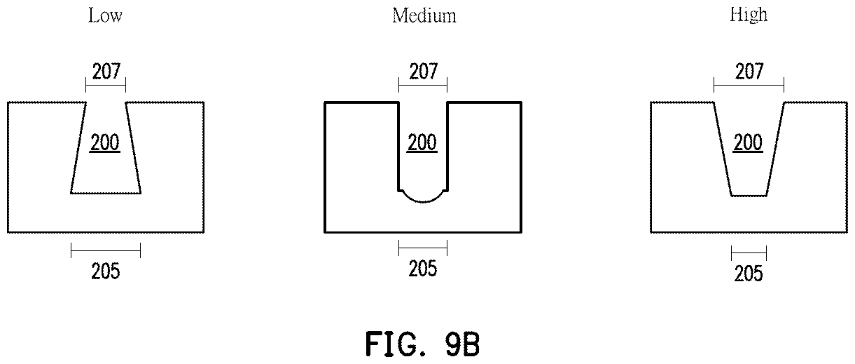

Next, in step 340 of FIG. 2 and as illustrated in FIG. 9A, a plurality of S/D trenches 200 are etched within each LDD region to form S/D regions 220. Each S/D trench 200 passes through an LDD region 120, 130 and extends into the substrate 110. This etching step is typically performed by dry etching, and an anisotropic etch profile is desired. In more particular embodiments, the etching gas may be a mixture of HBr/O₂/H₂ in desired ratios to obtain the desired shape for the trenches. As illustrated here, three spaced-apart trenches are formed within each LDD region 120, 130. It is especially noted that the S/D trenches do not extend below the gate spacer. Thus, with respect to the semiconductor channel 230, depending on the dimensions of the optional first sealing layer 170, the optional second sealing layer 180, and the gate spacer 190, the distance 236 between the S/D trench and the channel 230 may be a minimum of 10 nanometers.

FIG. 9B is a set of S/D trench cross-sectional etching profiles that can be formed, depending on the concentration of secondary etchant in the etching gas. In this regard, the removal of substrate material forms the trenches. Byproducts of the etching process may form a protective layer on the exposed substrate within the trench, such that the etch rate is greater at the bottom of the trench than near the upper surface of the substrate where the trench surface is covered with the protective layer. The secondary etchant is more selective for the protective layer, thus removing the protective layer from the trench surface. When the concentration of secondary etchant is “low”, the resulting trench 200 has a trapezoidal cross-section, with the width 205 at the bottom of the trench being greater than the width 207 at the top of the trench. When the concentration of secondary etchant is “medium”, the resulting trench 200 has substantially vertical walls, such that the width 205 at the bottom of the trench is substantially equal to the width 207 at the top of the trench. When the concentration of secondary etchant is “high”, the resulting trench 200 has a trapezoidal cross-section, with a smaller width 205 at the bottom of the trench compared to the width 207 at the top of the trench. This etch profile may be referred to as a “necking” profile. It is noted that the surface at the bottom of the trench may be curved rather than linear. In particular embodiments, the S/D trenches have a necking profile.

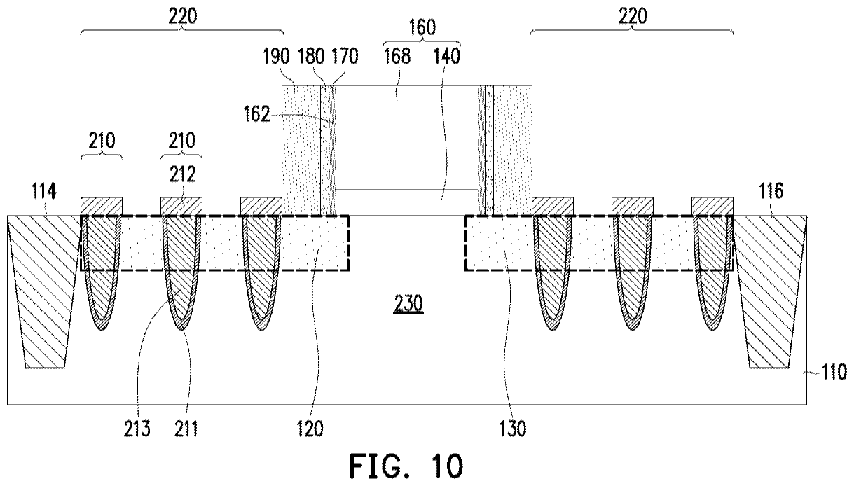

Then, in step 345 of FIG. 2 and as illustrated in FIG. 10, a strained source and drain (SSD) structure 210 is formed within each S/D trench. Again, the SSD structures do not extend below the gate spacer 190.

In some embodiments, the SSD structure is formed by an epitaxy or epitaxial (epi) process. Examples of such processes include selective epitaxy growth (SEG) process, vapor-phase epitaxy (VPE), molecular beam epitaxy (MBE), and some CVD deposition techniques. Typically, gaseous precursors are used which may interact with each other and/or the substrate. Doping species may be introduced during the epitaxial process by introducing doping species. Those may include p-type dopants such as germanium (Ge) or boron (B); or n-type dopants, such as phosphorus (P) or arsenic (As). Alternatively, an ion implantation process can be used to dope the SSD structures.

The SSD structure may be grown upon the surfaces of the S/D trench, and eventually fill the trench and also form a capping portion 212. As previously discussed, the dopant concentration may increase going from the perimeter/walls 211 of the SSD structure to the center 213 of the SSD structure. Put another way, the dopant concentration increases as the distance from the walls of the trench increases. The lower dopant concentration adjacent the un-doped silicon substrate aides in lowering the Schottky barrier. The higher dopant concentration near the center of the SSD structure can reduce source/drain contact resistance. The dopant concentration can be changed by varying the ratios of the gaseous precursors. In some particular embodiments, the SSD structures are formed from SiP (for NMOS) or SiGe (for PMOS). In some embodiments, annealing can be performed to activate the dopants in the SSD structure. As a result, the semiconductor channel 230 is strained or stressed to increase carrier mobility within the channel.

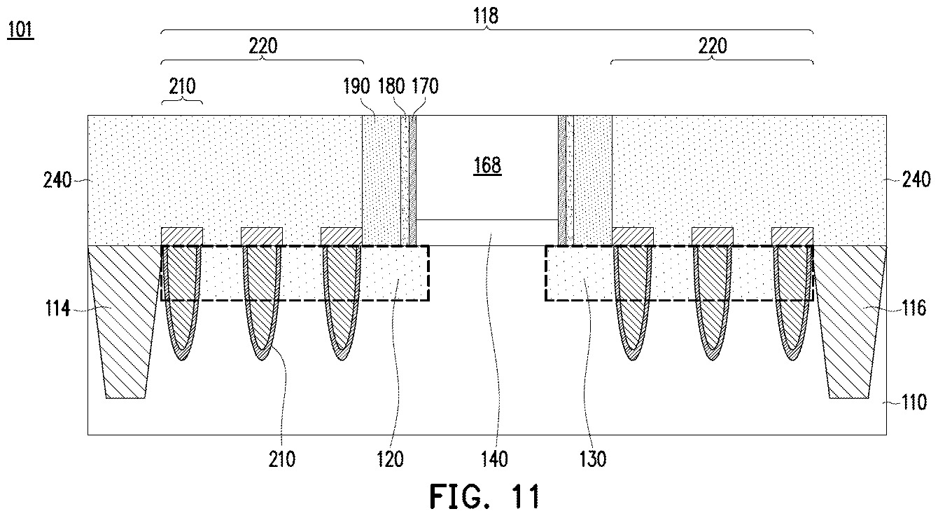

As discussed in step 350 of FIG. 2 and as illustrated in FIG. 11, an interlayer dielectric (ILD) material can be applied over the S/D regions 220 to form ILD regions 240. The ILD regions electrically separate the source/drain regions from the final gate structure or electrode. The ILD regions may be formed from any dielectric material, and do not need to be a high-k dielectric material. The ILD material can be deposited using any appropriate method, for example CVD.

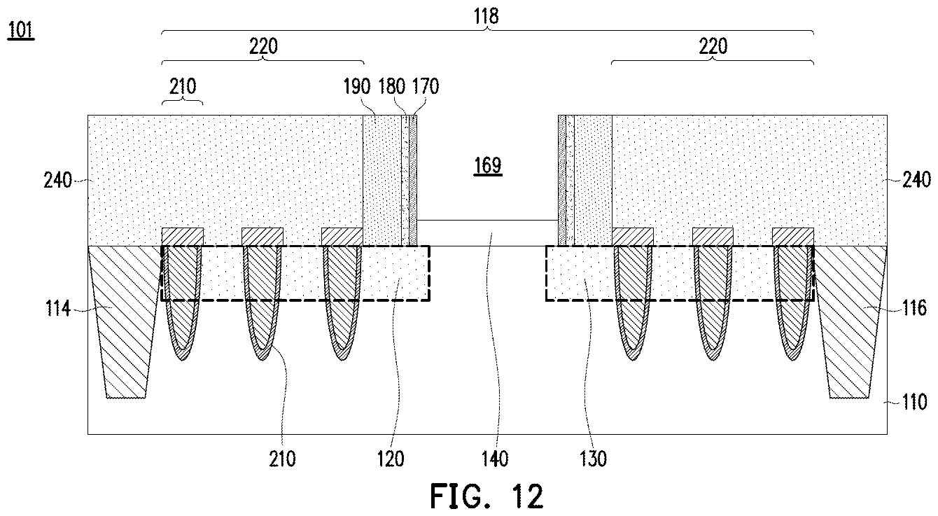

Continuing, then, in step 355 of FIG. 2 and as illustrated in FIG. 12, the dummy gate is removed to form a gate volume 169. This may be done by etching or other suitable process. Then, in step 360 of FIG. 2, an electrically conductive gate material is deposited to fill the gate volume and form a gate structure 150. Suitable gate materials may include, for example, a metal such as W, TiN, TiAl, Pt, Co, Rh, Pd, Ti, Ta, and the like, or doped polysilicon. The resulting structure is shown in FIG. 1A and FIG. 1B, which were previously discussed above.

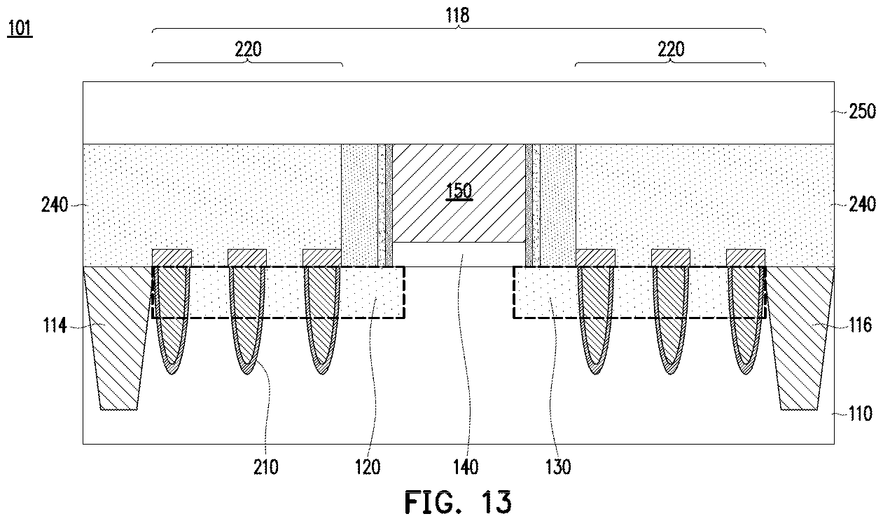

Further processing may occur to package the transistor. For example, next, in step 365 of FIG. 2 and as illustrated in FIG. 13, a first insulating layer 250 is formed over the active region 118 that includes the S/D regions 220 and the gate structure 150. This layer may be formed using processes such as PVD, CVD, SACVD, or other suitable deposition process. The material for the first insulating layer may be silicon or other suitable dielectric material (e.g. silicon dioxide).

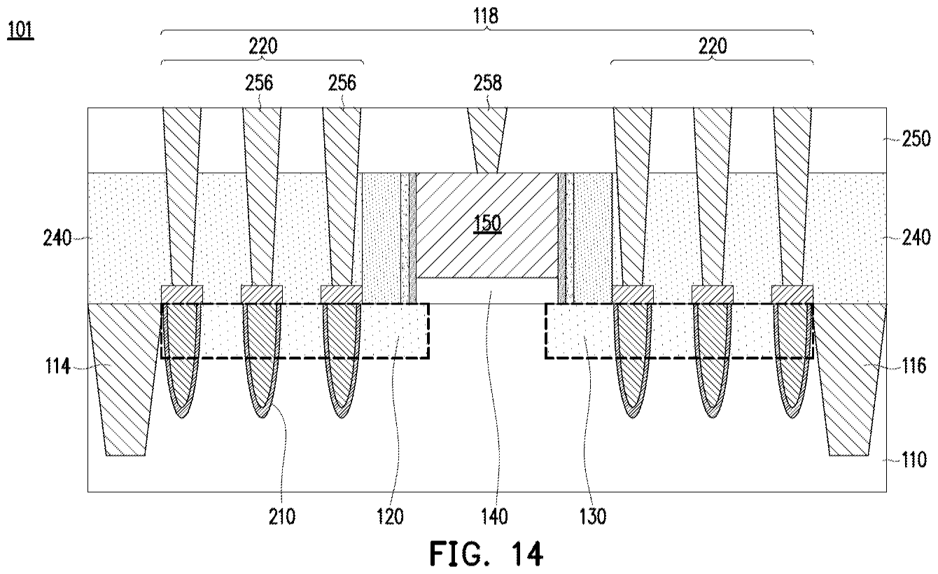

Then, in step 370 of FIG. 2 and as illustrated in FIG. 14, etching is performed to form openings that extend through the first insulating layer 250 and the ILD regions 240 to the SSD structures 210 in the S/D regions 220 and the gate structure 150. In step 375, the openings are then filled with an electrically conductive material to form source/drain vias 256 and a gate via 258. It is noted that as illustrated here, a via 256 is formed to each SSD structure 210.

The vias 256, 258 themselves may be sufficient to act as an electrode (i.e. a source electrode, a drain electrode, and a gate electrode) for further processing steps. If a larger contact footprint is desired, these steps can be repeated.

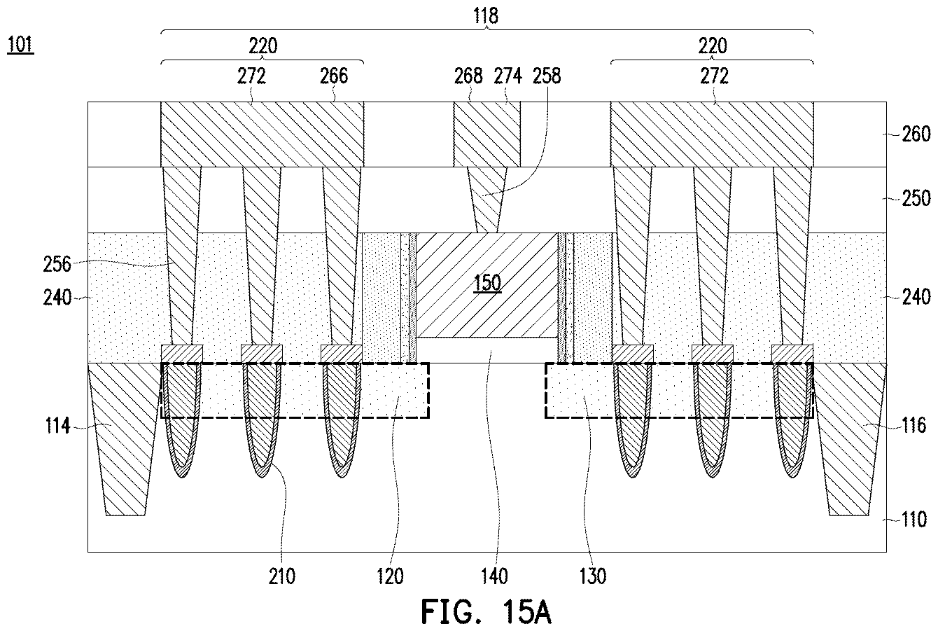

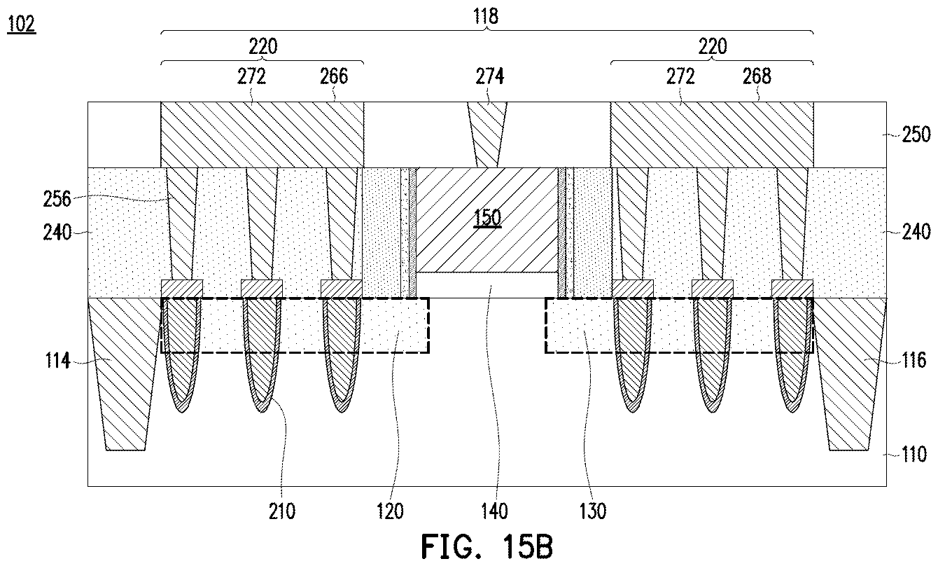

For example, in step 380 of FIG. 2 and as illustrated in FIG. 15A, a second insulating layer 260 is formed upon the first insulating layer 250 and over the active region 118 that includes the S/D regions 220 and the gate structure 150. Then, in step 385 of FIG. 2, etching is performed to form openings that extend through the second insulating layer 260 to the vias 256, 258 in the first insulating layer. In step 390, the openings are then filled with an electrically conductive material to form source/drain pads 266 and a gate pad 268. It is noted that as illustrated here, the S/D pads 266 contact multiple vias 256 to the SSD structures 210, such that the SSD structures in each LDD region are electrically connected together. In this embodiment, the S/D electrodes 272 are formed from the combination of an S/D via 256 and an S/D pad 266. The gate electrode 274 is formed from the combination of a gate via 258 and a gate pad 268.

FIG. 15B is a perspective view of yet another embodiment of the packaged transistor 102. In this embodiment, only the first insulating layer 250 is applied. Source/drain vias 256 are formed through the ILD regions 240. The S/D pads 272 are then formed in the first insulating layer to join the S/D vias together and form an S/D electrode 272. A gate electrode 274 is also formed in the first insulating layer.

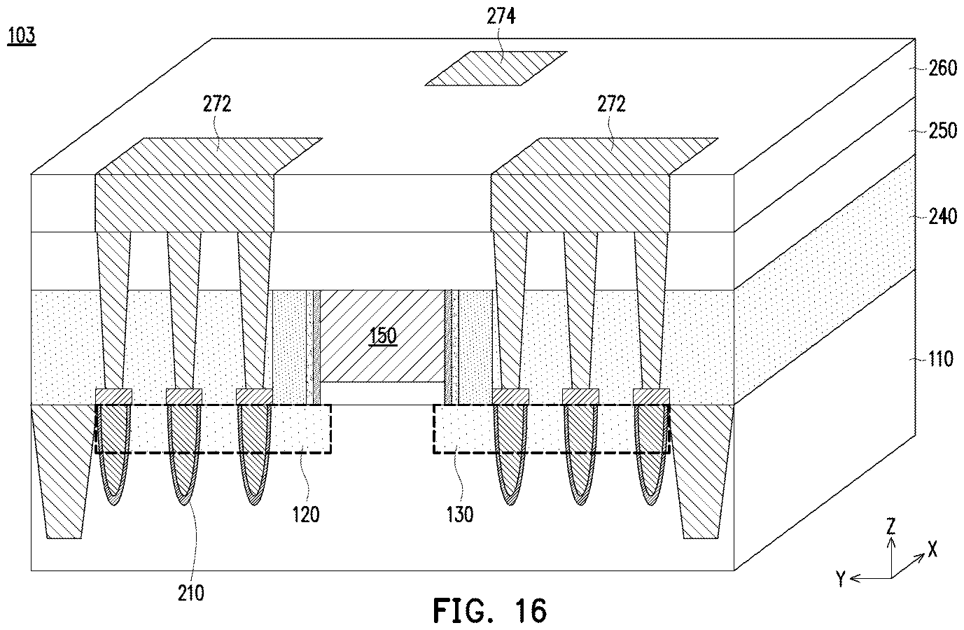

FIG. 16 is a perspective view of another embodiment of the packaged transistor 103. It is noted that the gate electrode 274 can be separated in the direction of the X-axis from the S/D electrodes 272.

The transistors and methods of the present disclosure include several different dielectric structures. Such dielectric structures can generally be made from any suitable combination of dielectric materials, although the characteristics of any particular layer may also be further defined. Examples of dielectric materials may include silicon dioxide (SiO₂), silicon nitride (Si₃N₄), silicon carbide (SiC), hafnium dioxide (HfO₂), zirconium dioxide (ZrO₂), aluminum oxide (Al₂O₃), silicon oxynitride (SiOₓN_{y}), hafnium oxynitride (HfOₓN_{y}) or zirconium oxynitride (ZrOₓN_{y}), or hafnium silicates (ZrSiₓO_{y}) or zirconium silicates (ZrSiₓO_{y}) or silicon carboxynitride (SiCₓO_{y}N_{z}), or hexagonal boron nitride (hBN). Other dielectric materials may include tantalum oxide (Ta₂O₅), nitrides such as silicon nitride, polysilicon, phosphosilicate glass (PSG), fluorosilicate glass (FSG), undoped silicate glass (USG), high-stress undoped silicate glass (HSUSG), and borosilicate glass (BSG).

It is also noted that certain conventional steps are not expressly described in the discussion above. For example, a pattern/structure may be formed in a given layer by applying a photoresist layer, patterning the photoresist layer, developing the photoresist layer, and then etching.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the photoresist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90° C. to about 110° C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern. One example of a common developer is aqueous tetramethylammonium hydroxide (TMAH). Generally, any suitable developer may be used. Sometimes, a post develop bake or “hard bake” may be performed to stabilize the photoresist pattern after development, for optimum performance in subsequent steps.

Continuing, portions of the layer below the patterned photoresist layer are now exposed. Etching transfers the photoresist pattern to the layer below the patterned photoresist layer. After use, the patterned photoresist layer can be removed, for example, using various solvents such as N-methyl-pyrrolidone (NMP) or alkaline media or other strippers at elevated temperatures, or by dry etching using oxygen plasma.

Generally, any etching step described herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), nitrogen trifluoride (NF₃), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

Planarization of a surface may be performed, for example, using a chemical mechanical polishing (CMP) process. Generally, CMP is performed using a rotating platen to which a polishing pad is attached. The substrate is attached to a rotating carrier. A slurry or solution containing various chemicals and abrasives is dispensed onto the polishing pad or the wafer substrate. During polishing, both the polishing pad and the carrier rotate, and this induces mechanical and chemical effects on the surface of the wafer substrate and/or the top layer thereon, removing undesired materials and creating a highly level surface. A post-CMP cleaning step is then carried out using rotating scrubber brushes along with a washing fluid to clean one or both sides of the wafer substrate.

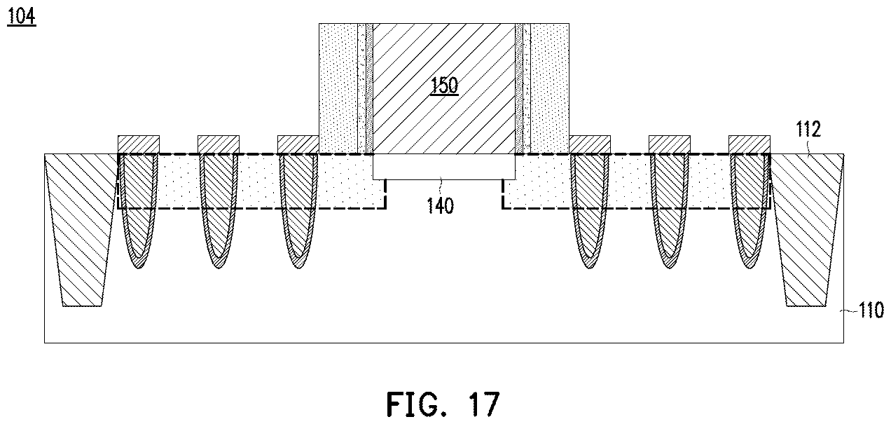

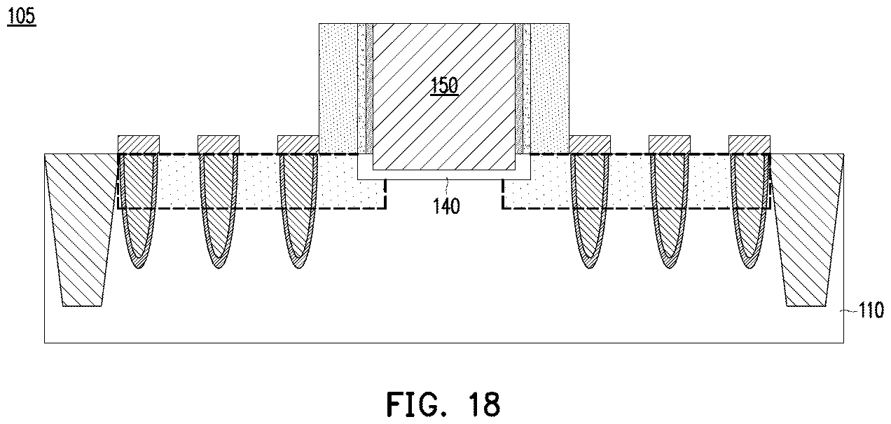

Some variations on the transistor structure are contemplated. FIG. 17 is a Y-axis cross-sectional view of another embodiment of a transistor 104. In this embodiment, the gate dielectric layer 140 is formed in a recess in the substrate, or in other words is present below the upper surface 112 of the substrate 110. The gate dielectric layer fills the recess. FIG. 18 is a Y-axis cross-sectional view of another embodiment of a transistor 105. Here, both the gate dielectric layer 140 and the gate structure 150 extend into a recess in the substrate 110. The gate dielectric layer may be considered to cover the surfaces of the recess. This may be desirable to better control the thickness of the gate dielectric layer 140 and avoid impacts on the lowermost interconnect layer (M1).

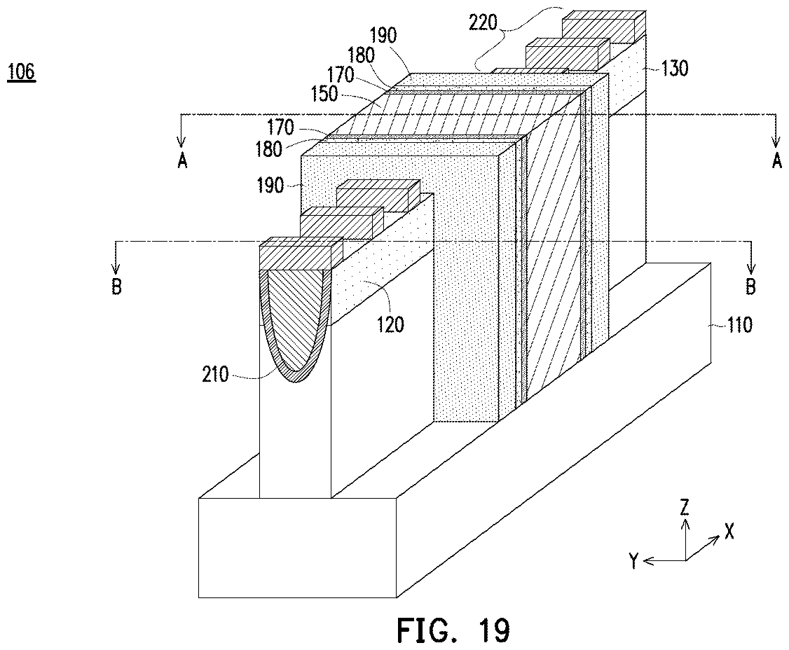

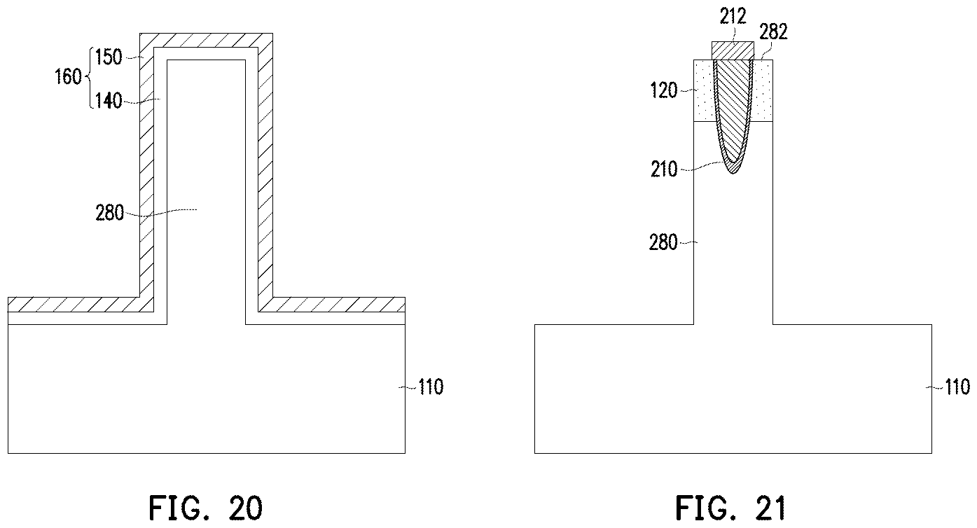

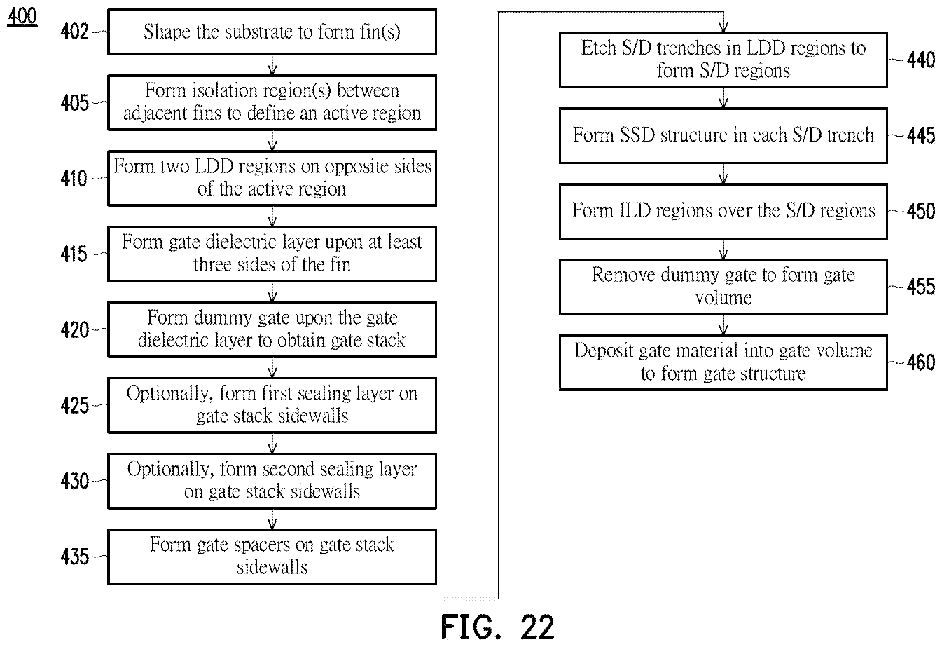

FIG. 19 is a perspective view of another embodiment of the transistor, in accordance with some embodiments of the present disclosure. Here, the transistor 106 is in the form of a FinFET with a three-dimensional structure in which a fin 280 rises above the substrate 110. FIG. 20 is a Y-axis cross-sectional view through line A-A of FIG. 19, and FIG. 21 is a Y-axis cross-sectional view through line B-B of FIG. 19.

Referring first to FIG. 19 and FIG. 20, the gate dielectric layer 140 and the gate structure 150 form a gate stack 160 that is present on three sides of the fin 280. LDD regions 120, 130 are visible. Here, the S/D regions 220 are illustrated as being part of the fin, although they can also be a separate structure connected to the ends of multiple fins. The first and second sealing layers 170, 180 and the gate spacers 190 electrically isolate the SSD structures 210 from the gate stack 160. As seen in FIG. 19 and FIG. 21, the SSD structures 210 extend into the S/D region 220 and through the LDD region 120. The capping portion 212 of the SSD structure is above the upper surface 282 of the fin.

FIG. 22 is a flow chart illustrating a method 400 for forming the FinFET structure of FIGS. 19-21, in accordance with some embodiments.

Initially, in step 402, the substrate 110 is shaped to form one or more fins 280. Typically, one or more hardmask layers is/are applied to the substrate. Mandrels are then formed upon the hardmask layer(s) over the substrate. This can be done by depositing a mandrel material layer, forming a photoresist layer upon the mandrel material layer, exposing the photoresist to radiation and developing the photoresist layer to form a mandrel pattern, and then etching the mandrel material layer to form the mandrels. If desired, the mandrels are then used as a mask, and etching is performed through the hardmask layer(s) and into the substrate is performed to form the fins. Alternatively, in a process known as self-aligned double patterning (SADP), spacers are formed on the sidewalls of the mandrels, and the mandrels are then removed. The spacers are then used as a mask, and etching is performed through the hardmask layer(s) and into the substrate is performed to form the fins. Self-aligned quadruple patterning (SAQP) is a similar process, and can also be used to form the fins.

Many of the following steps are the same as those in the method of FIG. 2, suitably modified for a FinFET. In step 405, isolation regions such as STI regions are formed between adjacent fins, to define an active region. In step 410, two lightly doped drain (LDD) regions are formed on opposite sides of the active region 118. In step 415, a gate dielectric layer 140 is formed upon three sides of the fin. Again, the gate dielectric layer overlaps the two LDD regions. In step 420, a dummy gate 168 is formed upon the gate dielectric layer 140 to create a gate stack 160. The dummy gate also overlaps the two LDD regions. In optional steps 425 and 430, a first sealing layer 170 and a second sealing layer 180 may be formed upon the sidewalls of the gate stack 160. In step 435, gate spacers 190 are formed upon the sidewalls of the gate stack. The gate spacers are also located over the LDD regions. In step 440, a plurality of S/D trenches are etched within each LDD region to form S/D regions 450. In step 445, an SSD structure is formed within each S/D trench. In step 450, ILD regions are formed over the S/D regions (note this step is not illustrated in FIGS. 19-21). In step 455, the dummy gate is removed to form a gate volume. In step 460, an electrically conductive gate material is deposited to fill the gate volume and form a gate structure 150 in the form of a gate electrode layer. The resulting structure is shown in FIGS. 19-21, without the ILD regions. Process steps 365-390 of FIG. 2 may also be performed to package the FinFET.

The combination of the LDD regions with the SSD structures increases the S/D junction breakdown voltage and also allows for a relatively uniform electric field at the surface of the transistor. This accomplishes the same results as RESURF (Reduced Surface Field), in which a PN junction is constructed below the drain in a transistor such that a depletion layer extending from the PN junction reaches the device surface, but without the additional processing steps that are needed for such a structure. In addition, the dopant concentrations in the SSD structures can be increased to reduce the surface electric field without a reduction in the S/D junction breakdown voltage

The transistors of the present disclosure can be used in high voltage, medium voltage, and low voltage devices on chips. High voltage devices typically operate from about 12 volts (V) to about 28V. Medium voltage devices typically operate from about 3V to about 9V. Low voltage devices usually operate below 1V.

Additional processing steps may be performed to fabricate a semiconductor device or integrated circuit with additional structures. Examples of such steps may include ion implantation, deposition of other materials, etching, etc.

The semiconductor devices might be used in various applications such as BCD (Bipolar-CMOS-DMOS) circuits for driving discrete high voltage components; drivers for LCD, OLED, AMOLED, or QLED display panels; image sensors that can be used in systems such as mobile telephones, facial recognition systems, or as motion sensors for automotive applications, security applications, energy efficiency, etc.; power management devices that control the flow and direction of electrical power; and/or image signal processors (ISP).

Some embodiments of the present disclosure thus relate to methods for forming a transistor. Lightly doped drain (LDD) regions are formed in a substrate on opposite sides of an active region. A gate stack is formed upon the substrate that overlaps the LDD regions. The gate stack includes a gate dielectric layer and a dummy gate upon the gate dielectric layer. A gate spacer is formed on sidewalls of the gate stack upon the LDD regions. A plurality of S/D trenches is etched within each LDD region to form S/D regions. A strained source and drain (SSD) structure is formed within each S/D trench. The SSD structures do not extend below the gate spacers.

Also disclosed in various embodiments are transistors that comprise a substrate, a gate stack, LDD regions; a gate spacer, and SSD structures. The gate stack is located upon the substrate, and includes a gate dielectric layer and a gate structure upon the gate dielectric layer. A first lightly doped drain (LDD) region and a second LDD region extend away from below the gate stack towards opposite sides of the gate stack. The gate spacer is located on sidewalls of the gate stack, and upon the first and second LDD regions. A plurality of strained source and drain (SSD) structures is present within each LDD region, wherein the SSD structures do not extend below the gate spacers.

Some other embodiments of the present disclosure relate to a transistor that comprises a substrate. The substrate comprises a fin that extends between two S/D regions. A gate dielectric layer is present upon at least three sides of the fin between the two S/D regions. A gate electrode layer is located upon the gate dielectric layer. A gate spacer is present on sidewalls of the gate electrode layer; Lightly doped drain (LDD) regions extend from each S/D region to below the gate dielectric layer. A plurality of strained source and drain (SSD) structures is present within each LDD region, wherein the SSD structures do not extend below the gate spacers.

Also disclosed are semiconductor devices comprising one or more transistors having the structures described above. The transistor(s) may be packaged, for example with ILD regions and insulating layer(s) as described above, with electrodes extending through the insulating layer(s).

The methods, systems, and devices of the present disclosure are further illustrated in the following non-limiting working examples, it being understood that they are intended to be illustrative only and that the disclosure is not intended to be limited to the materials, conditions, process parameters and the like recited herein.

### EXAMPLES

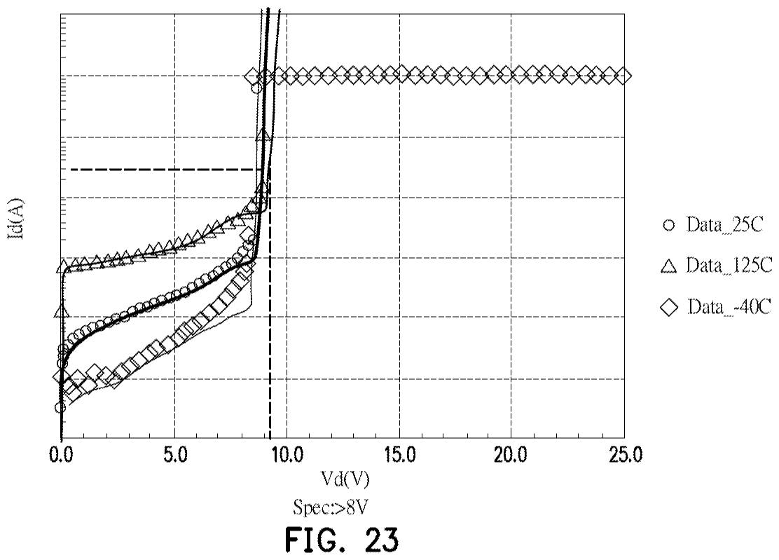

A transistor according to the present disclosure was tested at three different temperatures: −40° C., +25° C., and +125° C. FIG. 23 is a graph of drain leakage current vs. drain voltage at the three temperatures. As seen here, the leakage current does not appreciably increase until after the drain voltage is greater than 8V.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a transistor, comprising:
forming lightly doped drain (LDD) regions in a substrate on opposite sides of an active region;
forming a gate stack upon the substrate that overlaps the LDD regions, the gate stack including a gate dielectric layer and a dummy gate upon the gate dielectric layer;
forming a gate spacer on sidewalls of the gate stack upon the LDD regions;
etching a plurality of S/D trenches within each LDD region to form S/D regions; and
forming a strained source and drain (SSD) structure within each S/D trench, wherein the SSD structures do not extend below the gate spacers.

2. The method of claim 1, wherein each SSD structure has a dopant gradient concentration that increases from a perimeter towards a center of the SSD structure.

3. The method of claim 2, wherein the dopant concentration at the perimeter of the SSD structure is from about 1×10¹⁹ to about 5×10²⁰ atoms/cc.

4. The method of claim 2, wherein the dopant concentration at the center of the SSD structure is from about 5×10²⁰ to about 5×10²¹ atoms/cc.

5. The method of claim 1, wherein each SSD structure comprises SiP or SiGe.

6. The method of claim 1, wherein the gate spacer has a width of about 10 nm to about 100 nm.

7. The method of claim 1, wherein each SSD structure has a width of about 10 nm to about 100 nm.

8. The method of claim 1, wherein a spacing width of about 10 nm to about 100 nm is present between adjacent SSD structures.

9. The method of claim 1, wherein each S/D trench has a trapezoidal cross-section with a smaller width at a bottom of the recess.

10. The method of claim 1, further comprising, prior to forming the LDD regions, forming an isolation region in the substrate to define the active region.

11. The method of claim 1, further comprising, prior to forming the gate spacer, forming at least one sealing layer upon the sidewalls of the gate stack.

12. The method of claim 11, wherein each sealing layer has a width of about 10 nm to about 100 nm.

13. The method of claim 1, further comprising, after forming the SSD structures:
removing the dummy gate to form a gate volume;
depositing a gate material into the gate volume to form a gate structure;
applying an interlayer dielectric material over the S/D regions;
forming a first insulating layer over the active region;
etching openings through the first insulating layer to the S/D regions and the gate structure; and
filling the openings with an electrically conductive material to form at least one source via, at least one drain via, and a gate via.

14. The method of claim 13, further comprising:
forming a second insulating layer over the first insulating layer;
etching the second insulating layer to form pads over the vias; and
filling the pads with an electrically conductive material to form a source electrode, a drain electrode, and a gate electrode.

15. A transistor, comprising:
a substrate;
a gate stack upon the substrate that includes a gate dielectric layer and a gate structure upon the gate dielectric layer;
a first lightly doped drain (LDD) region and a second LDD region that extend away from below the gate stack towards opposite sides of the gate stack;
a gate spacer on sidewalls of the gate stack upon the first and second LDD regions; and
a plurality of strained source and drain (SSD) structures within each LDD region, wherein the SSD structures do not extend below the gate spacers.

16. The transistor of claim 15, wherein the SSD structures are in the form of a trench with a smaller width at a bottom of the trench than at a top of the trench.

17. The transistor of claim 15, wherein each SSD structure has a dopant gradient concentration that increases from a perimeter towards a center of the SSD structure.

18. A transistor, comprising:
a substrate comprising a fin that extends between two S/D regions;
a gate dielectric layer upon at least three sides of the fin between the two S/D regions;
a gate electrode layer upon the gate dielectric layer;
a gate spacer on sidewalls of the gate electrode layer;
lightly doped drain (LDD) regions extending from each S/D region to below the gate dielectric layer; and
a plurality of strained source and drain (SSD) structures within each LDD region, wherein the SSD structures do not extend below the gate spacers.

19. The transistor of claim 18, wherein a spacing width of about 10 nm to about 100 nm is present between adjacent SSD structures.

20. The transistor of claim 18, wherein each SSD structure has a dopant gradient concentration that increases from a perimeter towards a center of the SSD structure.
